(19) United States
(12) Patent Application Publication
(10) Pub. No.: US 2021/0136153 A1
(43) Pub. Date: May 6, 2021

(54) SERVER

(71) Applicant: LG ELECTRONICS INC., Seoul (KR)

(72) Inventors: Jaeyong Lee, Seoul (KR); Bohyun Jung, Seoul (KR)

(73) Assignee: LG ELECTRONICS INC., Seoul (KR)

(21) Appl. No.: 17/085,610

(22) Filed: Oct. 30, 2020

(30) Foreign Application Priority Data
Oct. 31, 2019 (KR) 10-2019-0137913

(51) Int. Cl. H04L 29/08; H01L 31/04; H01L 21/66

(52) U.S. Cl. CPC H04L 67/125; H01L 22/12; H01L 31/04

(57) ABSTRACT

The present disclosure relates to a server. The server includes a communicator configured to receive data from a plurality of process apparatuses for manufacturing a solar module; and a processor configured to select a feature from data received from the plurality of process apparatuses through learning, and perform an analysis on the plurality of process apparatuses based on the selected feature.

### CROSS-REFERENCE TO RELATED APPLICATION

This application claims the priority benefit of Korean Patent Application No. 10-2019-0137913, filed on, 31 Oct. 2019 in the Korean Intellectual Property Office, the disclosure of which is incorporated herein by reference.

### BACKGROUND OF THE INVENTION

### 1. Field of the Invention

The present disclosure relates to a server, and more particularly, to a server for increasing cell efficiency and increasing output of a solar module.

### 2. Description of the Related Art

A solar module includes a plurality of solar cells, and converts incident light into an electrical signal and outputs the electrical signal.

Meanwhile, a plurality of process apparatuses are used for manufacturing a solar module, and according to various descriptions, cell efficiency of the manufactured solar module is changed.

Therefore, it is preferable to increase the cell efficiency of the solar module by using various data from a plurality of process apparatuses, but a considerable amount of time and effort are required to process a huge amount of data from the plurality of process apparatuses.

### SUMMARY OF THE INVENTION

The present disclosure has been made in view of the above problems, and provides a server for increasing cell efficiency and increasing output of a solar module.

The present disclosure further provides a server for efficiently processing data from a plurality of process apparatuses.

In accordance with an aspect of the present disclosure, a server includes: a communicator configured to receive data from a plurality of process apparatuses for manufacturing a solar module; and a processor configured to select a feature from data received from the plurality of process apparatuses through learning, and perform an analysis on the plurality of process apparatuses based on the selected feature.

In accordance with another aspect of the present disclosure, a server includes: a communicator configured to receive data from a plurality of process apparatuses for manufacturing a solar module; and a processor configured to select a feature from data received from the plurality of process apparatuses through learning, wherein the processor changes the feature selected from the data received from the plurality of process apparatuses, based on cell efficiency of the solar module.

### BRIEF DESCRIPTION OF THE DRAWINGS

The above and other objects, features and advantages of the present disclosure will be more apparent from the following detailed description in conjunction with the accompanying drawings, in which:

FIG. 1 is a diagram showing an example of a solar system including a server according to an embodiment of the present disclosure;

FIG. 2 is a simplified internal block diagram of the server of FIG. 1;

FIG. 3 is an example of an internal block diagram of a processor of FIG. 2;

FIG. 4 is an example of an internal block diagram of a data processor of FIG. 3;

FIG. 5 is another example of an internal block diagram of the processor of FIG. 2; and

FIGS. 6A to 15B are diagrams for explaining the operation of the server of FIG. 1.

### DETAILED DESCRIPTION OF THE PREFERRED EMBODIMENTS

Reference will now be made in detail to the preferred embodiments of the present disclosure, examples of which are illustrated in the accompanying drawings. The suffixes “module” and “unit” in elements used in description below are given only in consideration of ease in preparation of the specification and do not have specific meanings or functions. Therefore, the suffixes “module” and “unit” may be used interchangeably.

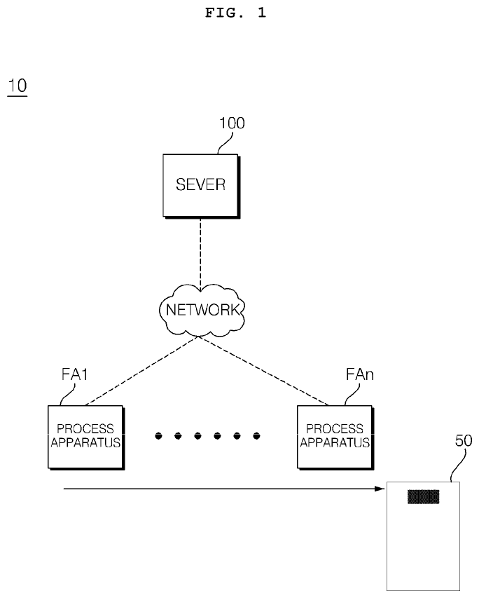

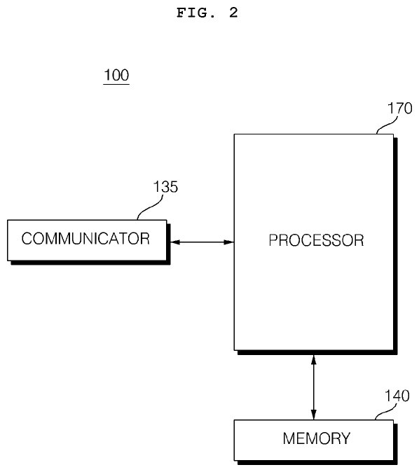

FIG. 1 is a diagram showing an example of a solar system including a server according to an embodiment of the present disclosure.

Referring to the drawing, a solar system 10a according to the embodiment of the present disclosure may include a plurality of process apparatuses FA1 to FAn for manufacturing a solar module 50 and a server 100.

The solar module 50 may include a solar cell module (not shown), and a junction box 200 including a power converter (not shown) for converting and outputting a DC power in the solar cell module.

The plurality of process apparatuses FA1 to FAn may include, for example, texturing apparatus, cleaning apparatus, LPCVD apparatus, etching apparatus, APCVD apparatus, activation apparatus, PECVD apparatus, printing apparatus, drying apparatus, inspection apparatus, sorting apparatus, and the like.

Meanwhile, the plurality of process apparatuses FA1 to FAn can transmit each sensing data, setting data, etc. to the server 100.

As the number of the plurality of process apparatuses FA1 to FAn increases, as the number of times of sensing, etc. increases, and the number of settings, etc. increases, the amount of data transmitted to the server 100 increases.

The server 100 has to collect and process such data, but in order to process a significant amount of data, an effective plan is needed.

Accordingly, according to an embodiment of the present disclosure, the server 100 includes a communicator 135 for receiving data from a plurality of process apparatuses FA1 to FAn for manufacturing the solar module 50, and a processor 170 that selects a feature from data received from the plurality of process apparatuses FA1 to FAn through learning, and performs analysis on the plurality of process apparatuses FA1 to FAn based on the selected feature. Accordingly, the cell efficiency can be increased and the output of the solar module 50 can be increased. In addition, the data from the plurality of process apparatuses FA1 to FAn can be efficiently processed.

Meanwhile, according to another embodiment of the present disclosure, the server 100 includes a communicator 135 for receiving data from a plurality of process apparatuses FA1 to FAn for manufacturing the solar module 50, and a processor 170 that selects a feature from data received from the plurality of process apparatuses FA1 to FAn through learning, and the processor 170 changes the feature selected from data received from the plurality of process apparatuses FA1 to FAn based on the cell efficiency of the solar module 50. Accordingly, the cell efficiency can be increased and the output of the solar module 50 can be increased. In addition, the data from the plurality of process apparatuses FA1 to FAn can be efficiently processed.

FIG. 2 is a simplified internal block diagram of the server of FIG. 1.

Referring to the drawing, the server 100 may include a communicator 135, a processor 170, and a memory 140.

The communicator 135 may receive data from the plurality of process apparatuses FA1-FAn.

For example, the communicator 135 may receive respective sensing data, setting data, and the like from a texturing apparatus, a cleaning apparatus, an LPCVD apparatus, an etching apparatus, an APCVD apparatus, an activation apparatus, a PECVD apparatus, a printing apparatus, a drying apparatus, an inspection apparatus, a sorting apparatus, and the like.

The memory 140 may store data necessary for the operation of the server 100.

For example, the memory 140 may store at least one learning model, prediction model for performing in the server 100. In this case, the learning model, the prediction model may include at least one of a general linear model (GLM), an artificial neural network (ANN) based on a deep neural network, and a Gaussian process (GP).

Meanwhile, the processor 170 may perform overall operation control of the server 100.

Meanwhile, the processor 170 may select a feature from data received from the plurality of process apparatuses FA1 to FAn, and analyze the plurality of process apparatuses FA1 to FAn based on the selected feature. Accordingly, the cell efficiency can be increased and the output of the solar module 50 can be increased. In addition, the data from the plurality of process apparatuses FA1 to FAn can be efficiently processed.

Meanwhile, the processor 170 may vary the feature selected from data received from the plurality of process apparatuses FA1 to FAn, based on the cell efficiency of the solar module 50.

Meanwhile, the processor 170 may divide a plurality of solar cells into a plurality of groups based on the cell efficiency of the solar module 50, and may select a first feature for moving from the first group among the plurality of groups to a second group having higher cell efficiency than the first group, from the data received from the plurality of process apparatuses FA1 to FAn.

Meanwhile, the processor 170 may select a second feature for moving from the second group among the plurality of groups to a third group having higher cell efficiency than the second group.

Meanwhile, the processor 170 may control to output an analysis result based on the analysis.

Meanwhile, the processor 170 may output factor information related to cell efficiency according to an analysis result based on the analysis.

Meanwhile, the processor 170 may receive structured data including sensor data and measurement data from the plurality of process apparatuses FA1 to FAn, and may receive unstructured data including machine log data, sensor log data, and alarm log data from the plurality of process apparatuses FA1 to FAn.

In this case, the sensor data may include temperature data and humidity data.

Meanwhile, the processor 170 may generate a table for integrated analysis based on the structured data and the unstructured data, and select a feature by performing modeling based on the table.

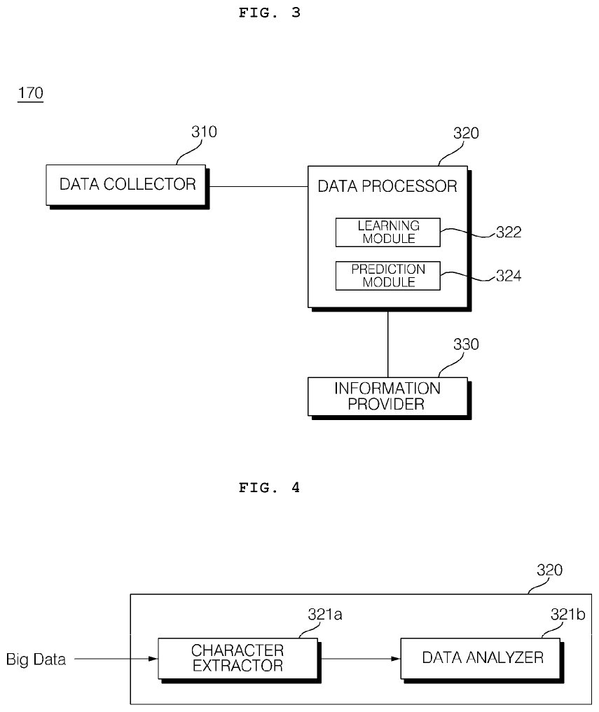

FIG. 3 is an example of an internal block diagram of a processor of FIG. 2.

Referring to the drawing, the processor 170 may include a data collector 310 and a data processor 320.

The data collector 310 may collect data from the plurality of process apparatuses FA1 to FAn for manufacturing the solar module 50.

For example, the data collector 310 may receive respective sensing data, setting data, and the like from a texturing apparatus, a cleaning apparatus, an LPCVD apparatus, an etching apparatus, an APCVD apparatus, an activation apparatus, a PECVD apparatus, a printing apparatus, a drying apparatus, an inspection apparatus, a sorting apparatus, and the like.

The data processor 320 may include a learning module 322 and a prediction module 324.

Meanwhile, the data processor 320 may process a part of respective sensing data, setting data, and the like from the texturing apparatus, the cleaning apparatus, the LPCVD apparatus, the etching apparatus, the APCVD apparatus, the activation apparatus, the PECVD apparatus, the printing apparatus, the drying apparatus, the inspection apparatus, the sorting apparatus, and the like from the data collector 310.

For example, the data processor 320 may perform data processing based on data from a plurality of process apparatuses FA1 to FAn collected by the data collector 310 to select a feature, and may perform analysis for a plurality of process apparatuses FA1 to FAn based on the selected feature.

Meanwhile, the data processor 320 may vary the feature selected from data received from a plurality of process apparatuses FA1 to FAn based on the cell efficiency of the solar module 50.

Meanwhile, the data processor 320 may divide a plurality of solar cells into a plurality of groups based on the cell efficiency of the solar module 50, and may select a first feature for moving from the first group among the plurality of groups to a second group having higher cell efficiency than the first group, from the data received from the plurality of process apparatuses FA1 to FAn.

Meanwhile, the data processor 320 may select a second feature for moving from the second group among the plurality of groups to a third group having higher cell efficiency than the second group.

Meanwhile, the data processor 320 may receive structured data including sensor data and measurement data from the plurality of process apparatuses FA1 to FAn, and may receive unstructured data including machine log data, sensor log data, and alarm log data from the plurality of process apparatuses FA1 to FAn.

Meanwhile, the data processor 320 may generate a table for integrated analysis based on the structured data and the unstructured data, and select a feature by performing modeling based on the table.

Meanwhile, the learning module 322 in the data processor 320 performs learning based on the learning model or the prediction model, and the prediction module 324 in the data processor 320, as a result of learning, may perform data processing based on the data from the plurality of process apparatuses FA1 to FAn of the solar module 50 to predict or select a feature. Thus, the data from the plurality of process apparatuses can be efficiently processed.

Meanwhile, the data processor 320 may control to update the learning model or the prediction model. Accordingly, the feature can be accurately predicted or selected.

Meanwhile, an information provider 330 may control to output an analysis result based on the analysis.

Meanwhile, the information provider 330 may output factor information related to cell efficiency based on the analysis result.

FIG. 4 is an example of an internal block diagram of a data processor of FIG. 3.

Referring to the drawing, the data processor 320 may include a character extractor 321a for performing data processing based on data from a plurality of process apparatuses FA1 to FAn, and selecting a feature, and a data analyzer 321b for analyzing the plurality of process apparatuses FA1 to FAn based on the selected feature.

The character extractor 321a may vary the feature selected from data received from the plurality of process apparatuses FA1 to FAn based on the cell efficiency of the solar module 50.

The character extractor 321a may divide a plurality of solar cells into a plurality of groups based on the cell efficiency of the solar module 50, and may select a first feature for moving from the first group among the plurality of groups to a second group having higher cell efficiency than the first group, from the data received from the plurality of process apparatuses FA1 to FAn.

Meanwhile, the character extractor 321a may select a second feature for moving from the second group among the plurality of groups to a third group having higher cell efficiency than the second group. In this case, the second feature may be different from the first feature.

The data analyzer 321b may analyze data according to the selected feature, and may analyze what data has the greatest factor that affects the cell efficiency.

The data analyzer 321b may output an analysis result based on the analysis.

For example, the data analyzer 321b may output factor information related to cell efficiency based on the analysis result.

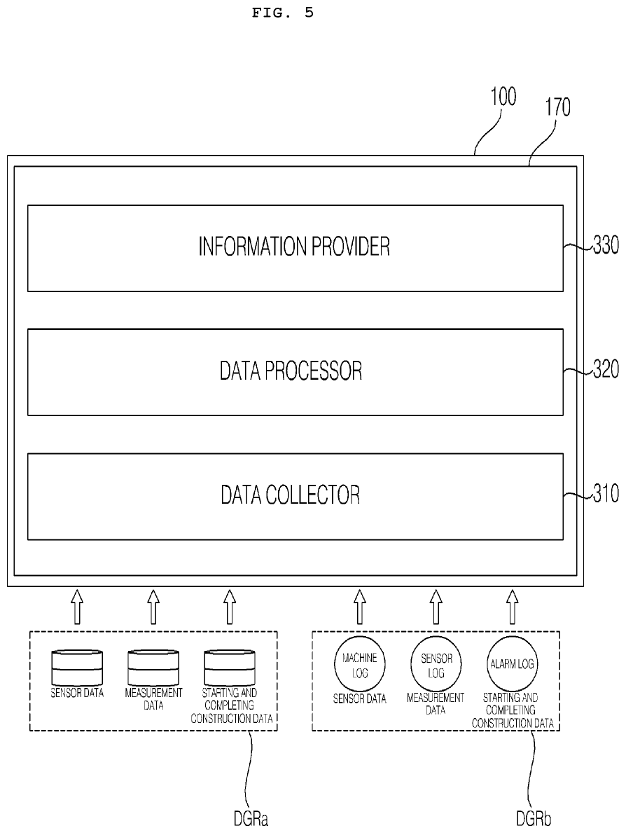

FIG. 5 is another example of an internal block diagram of the processor of FIG. 2.

Referring to the drawing, similarly to FIG. 3, the processor 170 may include a data collector 310, a data processor 320, and an information provider 330.

Operations of the data collector 310, the data processor 320, and the information provider 330 may correspond to the description of FIG. 3 respectively. Meanwhile, the processor 170 receives structured data including sensor data and measurement data from the plurality of process apparatuses FA1 to FAn, and may receive unstructured data including machine log data, sensor log data, and alarm log data from the plurality of process apparatuses FA1 to FAn.

In addition, the processor 170 may generate a table for integrated analysis based on the structured data and the unstructured data, and perform modeling based on the table to select a feature.

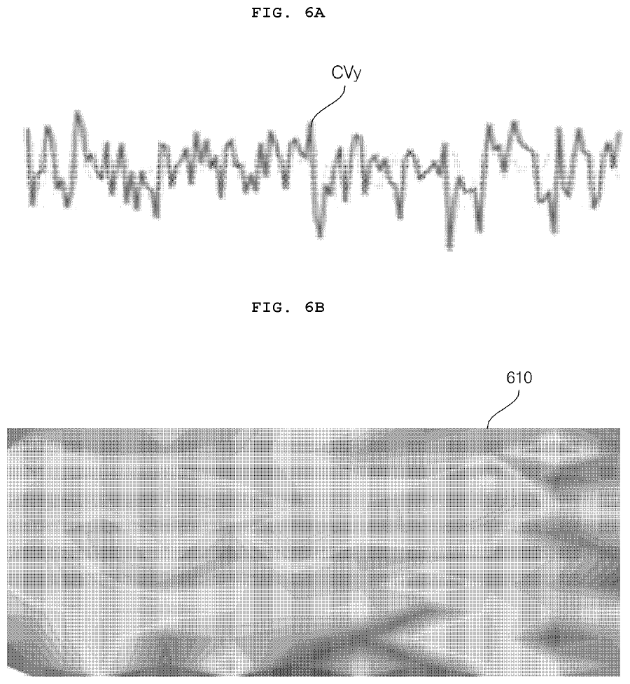

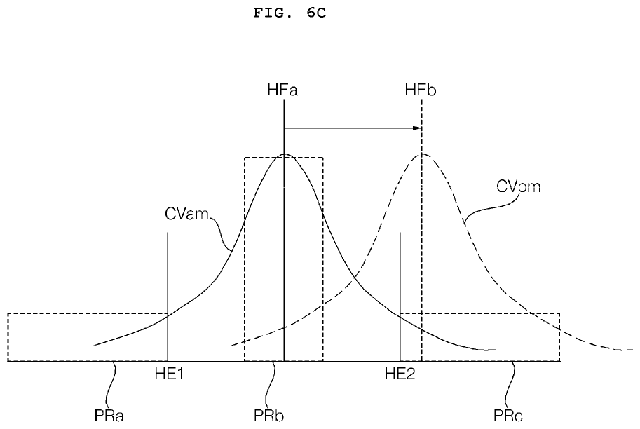

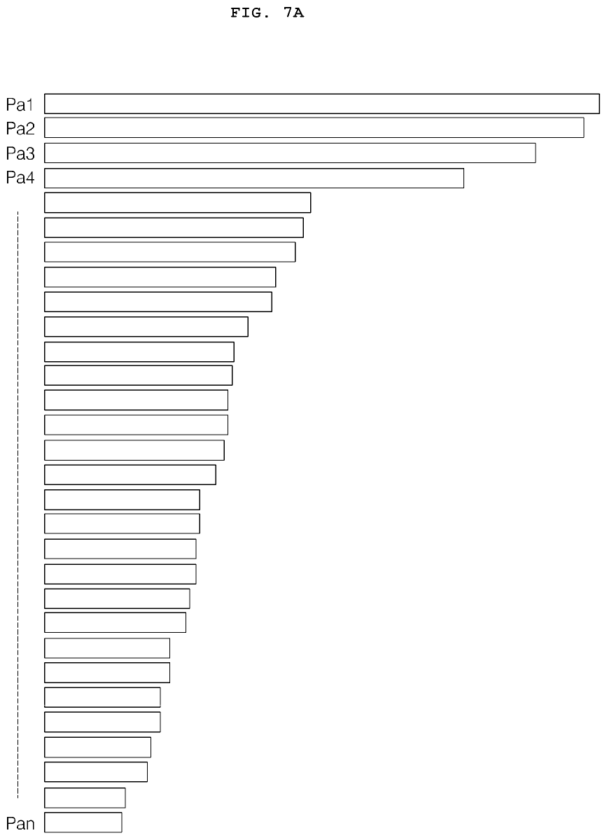

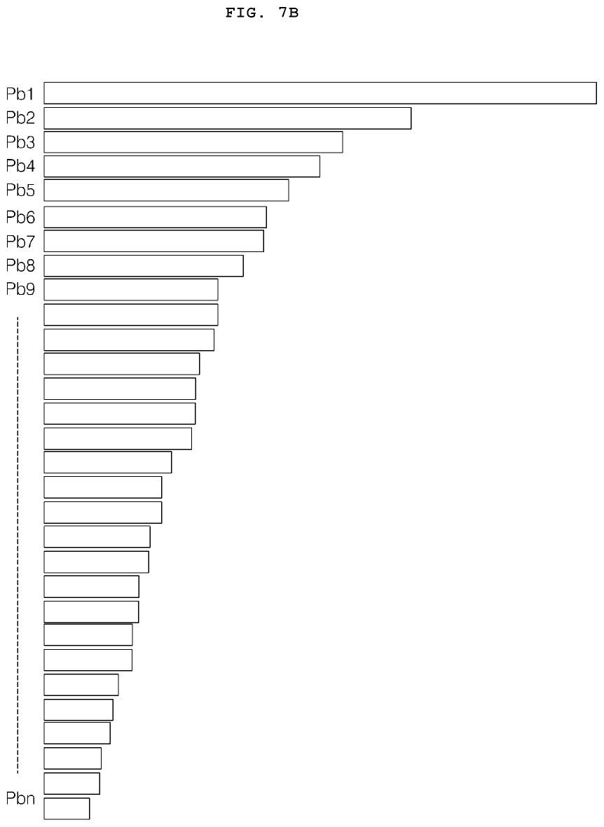

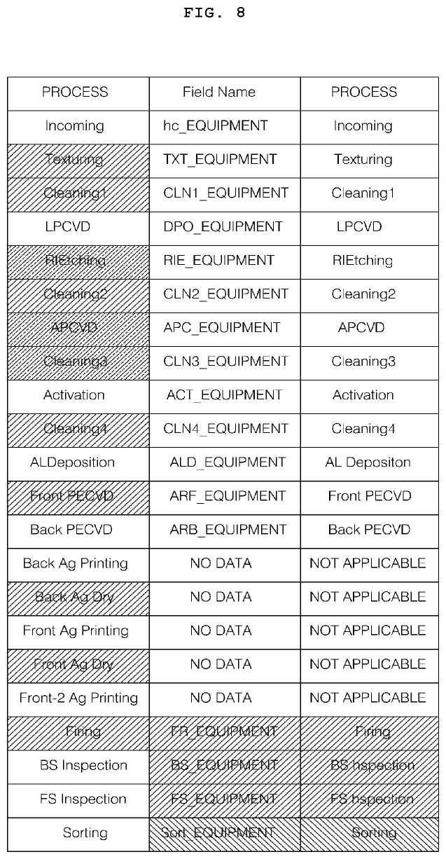

FIGS. 6A to 15B are diagrams for explaining the operation of the server of FIG. 1.

First, FIG. 6A illustrates a cell efficiency curve CVy indicating cell efficiency.

Cell efficiency may vary depending on various features.

Next, FIG. 6B illustrates a two-dimensional contour map 610 according to feature 1 and feature 2.

Feature 1 and feature 2 may be major factors influencing cell efficiency.

FIG. 6C illustrates a first cell efficiency curve CVam and a second cell efficiency curve CVbm.

The cell efficiency of a first solar module may be a first cell efficiency curve CVam, and the cell efficiency of a second solar module may be a second cell efficiency curve CVbm.

According to the first cell efficiency curve CVam, a low efficiency group PRa and a normal group PRb may be distinguished based on the cell efficiency.

According to the second cell efficiency curve CVbm, the normal group PRb and a high efficiency group PRc may be distinguished based on the cell efficiency.

The processor 170 in the server 100 may select a first feature for moving from the low efficiency group PRa of the plurality of groups to the normal group PRb having higher cell efficiency, from the data received from the plurality of process apparatuses FA1 to FAn.

Meanwhile, the processor 170 in the server 100 may select a second feature for moving from the normal group PRb of the plurality of groups to a higher efficiency group PRc having higher cell efficiency, from the data received from the plurality of process apparatuses FA1 to FAn.

In this case, the first feature and the second feature may be different.

In addition, the processor 170 in the server 100 may perform data processing based on data corresponding to the selected first and second features among data received from the plurality of process apparatuses FA1 to FAn.

In addition, the processor 170 in the server 100 may control to increase the cell efficiency by varying data corresponding to the first feature and the second feature.

For example, the processor 170 in the server 100 may derive and output optimal setting data, optimal temperature data, optimal humidity data, or the like of at least one process apparatus that affects cell efficiency through variations in data corresponding to the first feature and the second feature. Accordingly, the cell efficiency can be increased and the output of the solar module 50 can be increased. In addition, the data from the plurality of process apparatuses FA1 to FAn can be efficiently processed.

FIG. 7A illustrates data for dividing into the normal group PRb and the high efficiency group PRc by importance.

In the drawing, n data from Pal to Pan are illustrated. In this case, the processor 170 may select a certain number of data among the n data as a feature which is an important factor.

FIG. 7B illustrates data for dividing into the low efficiency group PRa and the normal group PRb by importance.

In the drawing, n data from Pb1 to Pbn are illustrated. In this case, the processor 170 may select a certain number of data among the n data as a feature which is an important factor.

Meanwhile, n data from Pal to Pan and n data from Pb1 to Pbn may be partially overlapped, but the order may be different.

FIG. 8 is a diagram illustrating information on a plurality of process apparatuses.

Referring to the drawing, the plurality of process apparatuses FA1 to FAn of FIG. 1 may include, for example, a texturing apparatus, a cleaning apparatus, an LPCVD apparatus, an etching apparatus, an APCVD apparatus, an activation apparatus, a PECVD apparatus, a printing apparatus, a drying apparatus, an inspection apparatus, a sorting apparatus, and the like.

The server 100 may receive data from a process apparatus that is operating in the texturing apparatus, the cleaning apparatus, the LPCVD apparatus, the etching apparatus, the APCVD apparatus, the activation apparatus, the PECVD apparatus, the printing apparatus, the drying apparatus, the inspection apparatus, the sorting apparatus, and the like.

In the drawing, there occurs no data from a Back Ag printing apparatus to a Front2 Ag printing apparatus, and data is generated in other apparatuses.

Meanwhile, the plurality of process apparatuses FA1 to FAn may transmit respective sensing data, setting data, and the like to the server 100.

As the number of the plurality of process apparatuses FA1 to FAn increases, as the number of sensing times, etc increases, and as the number of settings, etc increases, the amount of data transmitted to the server 100 increases.

The server 100 has to collect and process these data, but in order to process a significant amount of data, an effective plan is needed.

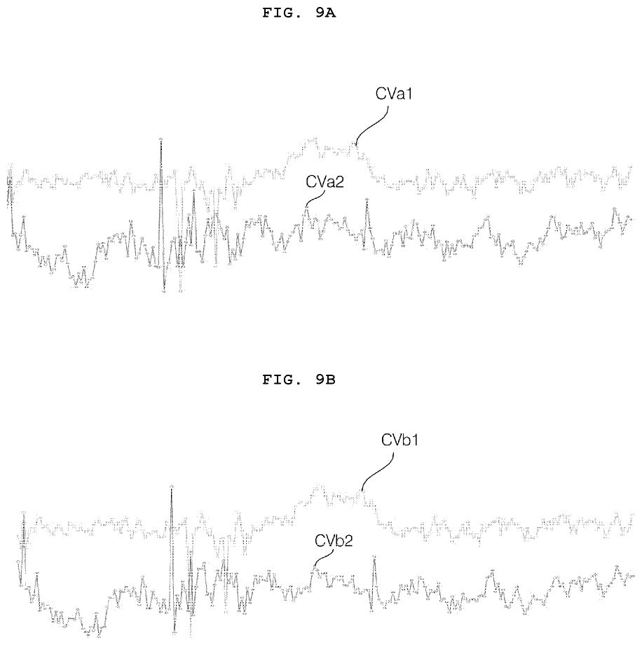

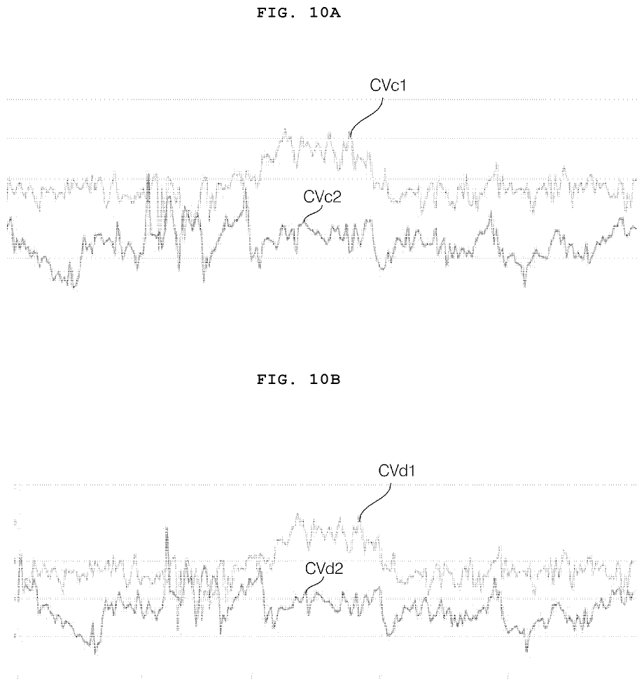

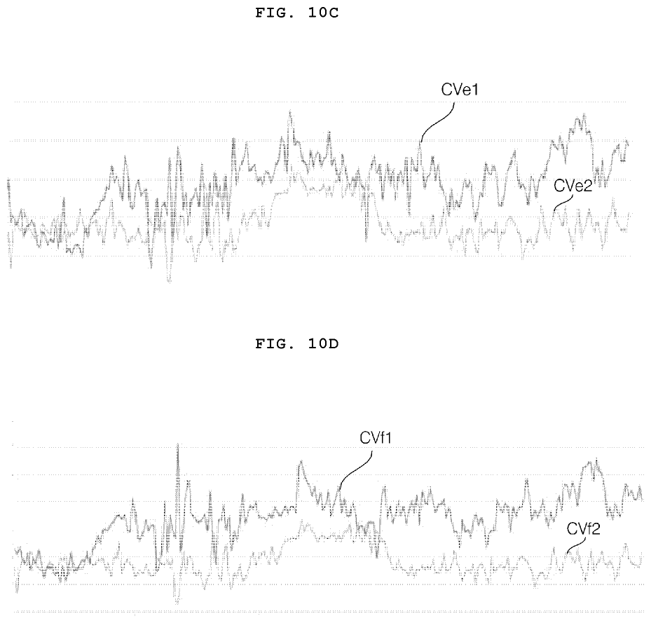

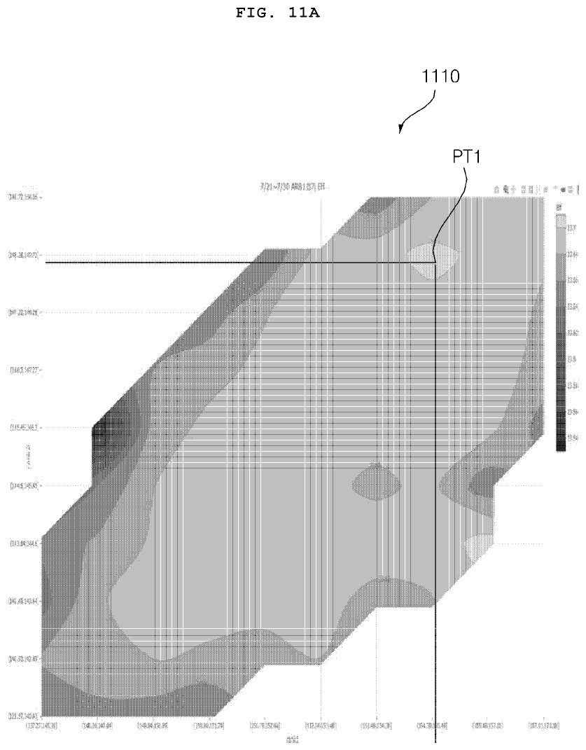

FIG. 9A is a diagram comparing a border thickness curve CVa2 and a cell efficiency curve CVa1 according to the border thickness of the solar module. Referring to the drawing, it can be seen that the cell efficiency changes, approximately in proportion to the border thickness. Therefore, the border thickness related to cell efficiency can be selected as a feature that is a major factor. FIG. 9B is a diagram comparing an inner thickness curve CVb2 and a cell efficiency curve CVb1 according to the inner thickness of the solar module. Referring to the drawing, it can be seen that the cell efficiency changes, approximately in proportion to the inner thickness. Therefore, the inner thickness related to cell efficiency can be selected as a feature that is a major factor.

FIG. 10A is a diagram comparing a border thickness curve CVc2 and a cell efficiency curve CVc1 according to the border thickness of the solar module in a first process apparatus, and FIG. 10B is a diagram comparing an inner thickness curve CVd2 and a cell efficiency curve CVd1 according to an inner thickness of a solar module in a first process apparatus.

FIG. 10C is a diagram comparing a border thickness curve CVe2 and a cell efficiency curve CVe1 according to the border thickness of the solar module in a second process apparatus, and FIG. 10D is a diagram comparing an inner thickness curve CVf2 and a cell efficiency curve CVf1 according to the inner thickness of a solar module in a second process apparatus.

In comparison with FIGS. 10A and 10B, it can be seen that the difference between the border thickness curve CVe2, and the cell efficiency curve CVe1, or the difference between the inner thickness curve CVf2 and the cell efficiency curve CVf1 in FIGS. 10C and 10D is smaller. Accordingly, the processor 170 may determine that the second process apparatus has a greater influence on cell efficiency than the first process apparatus.

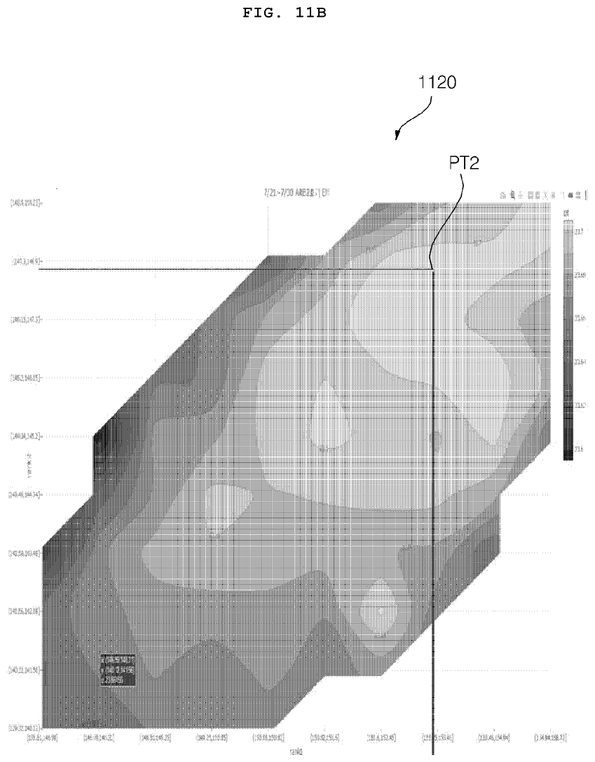

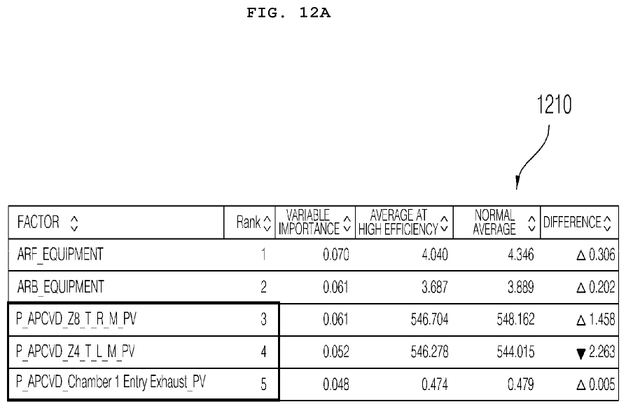

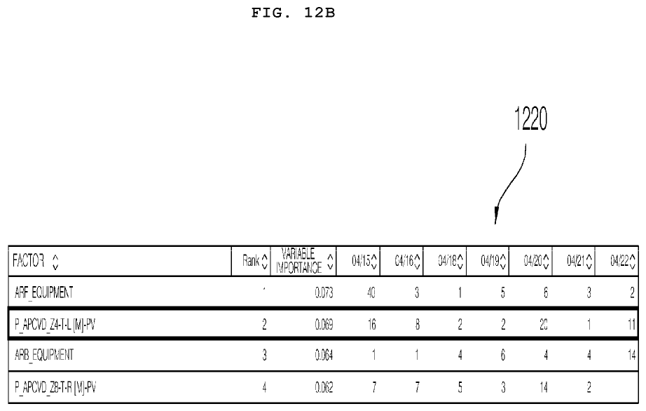

FIG. 11A illustrates a contour map of cell efficiency for the inner thickness versus the border thickness in a first process apparatus.

FIG. 11B illustrates a contour map of cell efficiency for the inner thickness versus border thickness in a second process apparatus.

When comparing FIGS. 11A and 11B, it can be seen that, in P11 and PT2, which are the most efficient points, the area to which PT2 belongs is larger than the area to which PT1 belongs.

Accordingly, the processor 170 may determine that the second process apparatus has a greater influence on cell efficiency, and has a higher cell efficiency than the first process apparatus.

Accordingly, the processor 170 may select at least some of the data in the second process apparatus rather than the first process apparatus as a feature.

FIG. 12A is a diagram illustrating the importance of variable data among a plurality of process apparatuses.

Referring to the drawing, data from rank 1 to rank 5 are illustrated sequentially from the high importance portion to the low importance portion.

Accordingly, the processor 170 may select a variable or data having high importance as a feature.

For example, data corresponding to rank 1 and rank 2 of rank 1 to rank 5 may be selected as a feature.

FIG. 12B is a diagram illustrating a recent importance trend in a plurality of process apparatuses.

Referring to the drawing, data from rank 1 to rank 4 are illustrated.

Meanwhile, it can be seen that the importance of the data of rank 2 has recently increased.

Accordingly, the processor 170 may select data corresponding to rank 2 which has recently increased in importance, as a feature.

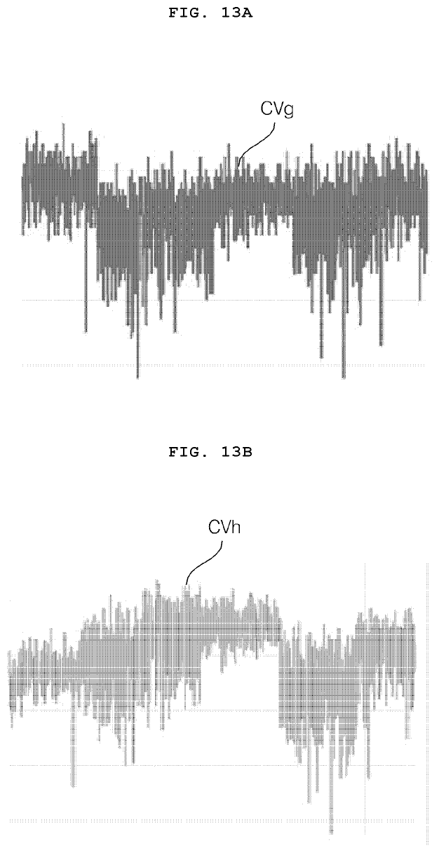

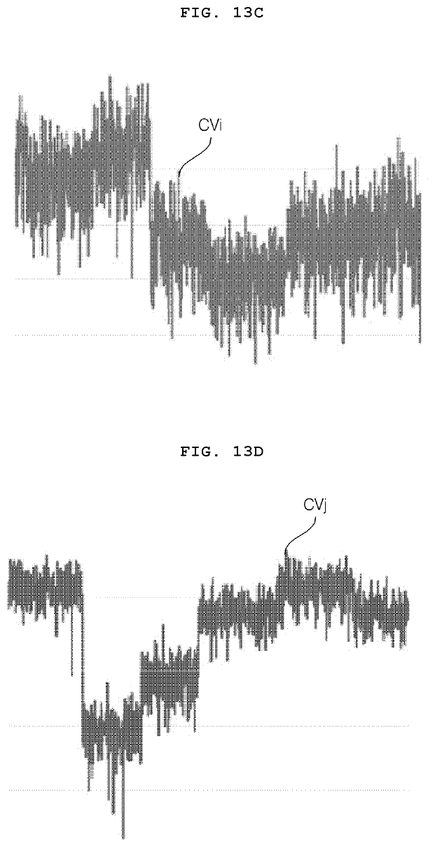

FIG. 13A illustrates a cell efficiency curve CVg of the sorting apparatus, FIG. 13B illustrates a FF curve CVh of the sorting apparatus, and FIG. 13C illustrates a voltage (Voc) curve CVi of the sorting apparatus, and FIG. 13D illustrates a current (Isc) curve CVk of the sorting apparatus. Referring to FIGS. 13A to 13D, it can be seen that the cell efficiency curve CVg is most similar to the FF curve CVh. Accordingly, the processor 170 may select data corresponding to the FF curve CVh as a feature.

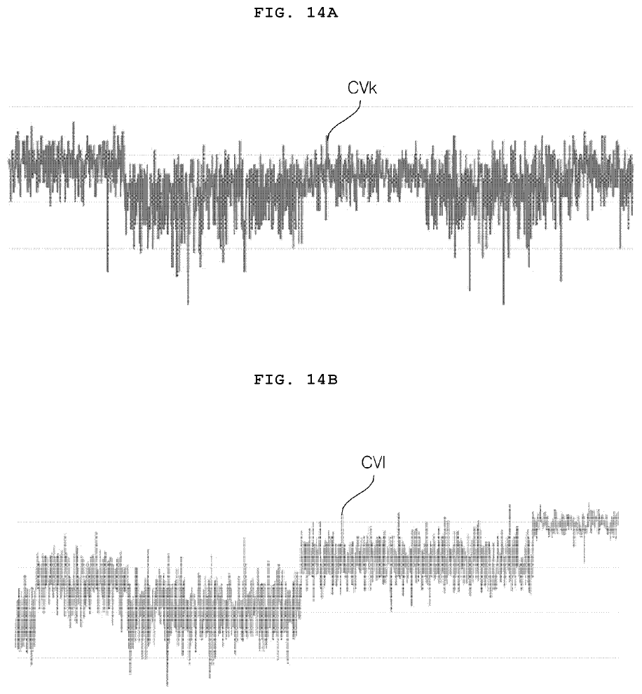

FIG. 14A illustrates the efficiency curve CVk, and FIG. 14B illustrates a specific data curve CV1.

Comparing FIG. 14A and FIG. 14B, it can be seen that a first period among an entire period including the first period, a second period, and a third period of the specific data curve CV1 is similar to the efficiency curve CVk.

Accordingly, the processor 170 may select data corresponding to the first period of the specific data curve CV1 as a feature.

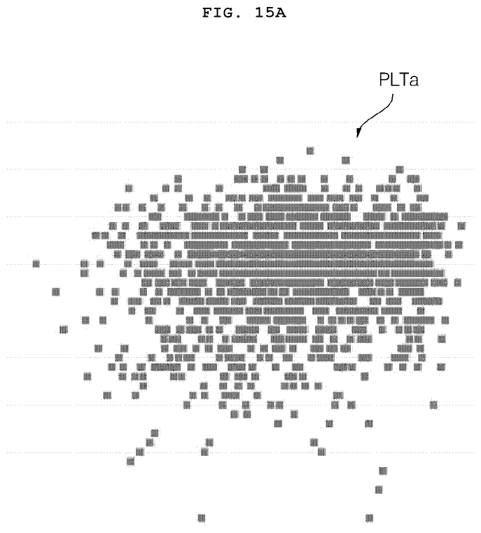

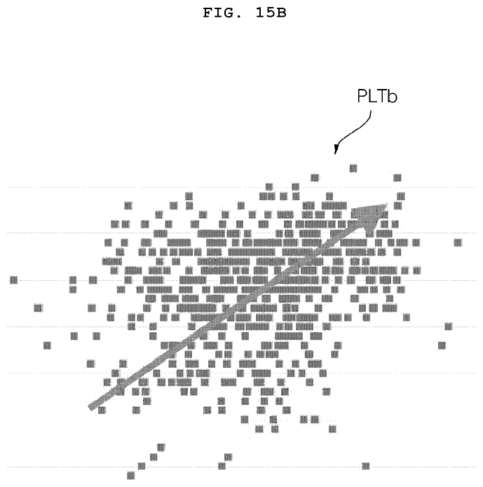

FIG. 15A is a two-dimensional diagram illustrating the relationship between the entire period of FIG. 14B and the cell efficiency, and FIG. 15B is a two-dimensional diagram illustrating the relationship between the first period of FIG. 14B and the cell efficiency.

Referring to the drawing, although the correlation between the entire period and the cell efficiency is not clearly shown in FIG. 15A, FIG. 15B shows the relationship, between the first period and the cell efficiency, which is approximately proportional.

Accordingly, the processor 170 may select data corresponding to the first period of a specific data curve CV1 as a feature.

After performing data analysis, etc according to the feature selection, the processor 170 in the server 100 may control to output an analysis result.

Accordingly, an optimum data setting, an optimum temperature setting, an optimum humidity setting, or the like in a plurality of process apparatuses can be achieved. As a result, a solar module having improved cell efficiency can be manufactured.

As described above, the server according to an embodiment of the present disclosure includes: a communicator configured to receive data from a plurality of process apparatuses for manufacturing a solar module; and a processor configured to select a feature from data received from the plurality of process apparatuses through learning, and perform an analysis on the plurality of process apparatuses based on the selected feature. Accordingly, the cell efficiency can be increased and the output of the solar module can be increased. In addition, data from the plurality of processing apparatuses can be efficiently processed.

The server according to another embodiment of the present disclosure includes a communicator configured to receive data from a plurality of process apparatuses for manufacturing a solar module; and a processor configured to select a feature from data received from the plurality of process apparatuses through learning, wherein the processor changes the feature selected from the data received from the plurality of process apparatuses, based on cell efficiency of the solar module. Accordingly, the cell efficiency can be increased and the output of the solar module can be increased. In addition, data from the plurality of processing apparatuses can be efficiently processed.

The server according to the embodiment of the present disclosure is not limited to the configuration and method of the embodiments described above, but all or part of respective embodiments are configured to be selectively combined so that various modifications can be achieved.

Although the exemplary embodiments of the present disclosure have been disclosed for illustrative purposes, those skilled in the art will appreciate that various modifications, additions and substitutions are possible, without departing from the scope and spirit of the invention as disclosed in the accompanying claims. Accordingly, the scope of the present disclosure is not construed as being limited to the described embodiments but is defined by the appended claims as well as equivalents thereto.

What is claimed is:

1. A server comprising:
a communicator configured to receive data from a plurality of process apparatuses for manufacturing a solar module; and
a processor configured to select a feature from data received from the plurality of process apparatuses through learning, and perform an analysis on the plurality of process apparatuses based on the selected feature.

2. The server of claim 1, wherein the processor changes the feature selected from the data received from the plurality of process apparatuses based on cell efficiency of the solar module

3. The server of claim 1, wherein the processor divides a plurality of solar cells into a plurality of groups based on the cell efficiency of the solar module, and selects a first feature for moving from a first group among the plurality of groups to a second group having higher cell efficiency than the first group, from the data received from the plurality of process apparatuses.

4. The server of claim 3, wherein the processor selects a second feature for moving to a third group having higher cell efficiency than the second group, from the second group among the plurality of groups.

5. The server of claim 1, wherein the processor controls to output an analysis result based on the analysis.

6. The server of claim 5, wherein the processor outputs factor information related to cell efficiency based on the analysis result.

7. The server of claim 1, wherein the processor comprises:
a data collector configured to collect data from the plurality of process apparatuses for manufacturing the solar module; and
a data processor configured to perform data processing based on the data from a plurality of process apparatuses collected by the data collector to select a feature, and perform analysis for the plurality of process apparatuses based on the selected feature.

8. The server of claim 7, wherein the processor further comprises an information provider for outputting analysis result information based on the analysis.

9. The server of claim 8, wherein the data processor comprises:
a character extractor configured to select a feature by performing data processing, based on the data from the plurality of process apparatuses; and
a data analyzer configured to perform analysis on the plurality of process apparatuses based on the selected feature.

10. The server of claim 1, wherein the processor receives structured data comprising sensor data and measurement data from the plurality of process apparatuses, and receives unstructured data comprising machine log data, sensor log data, and alarm log data from the plurality of process apparatuses.

11. The server of claim 10, wherein the sensor data comprises temperature data and humidity data.

12. The server of claim 10, wherein the processor generates a table for integrated analysis based on the structured data and the unstructured data, and selects a feature by performing modeling based on the table.

13. A server comprising:
a communicator configured to receive data from a plurality of process apparatuses for manufacturing a solar module; and
a processor configured to select a feature from data received from the plurality of process apparatuses through learning,
wherein the processor changes the feature selected from the data received from the plurality of process apparatuses, based on cell efficiency of the solar module.

14. The server of claim 13, wherein the processor divides a plurality of solar cells into a plurality of groups based on the cell efficiency of the solar module, and selects a first feature for moving from a first group among the plurality of groups to a second group having higher cell efficiency than the first group, from the data received from the plurality of process apparatuses.

15. The server of claim 14, wherein the processor selects a second feature for moving to a third group having higher cell efficiency than the second group, from the second group among the plurality of groups.

16. The server of claim 13, wherein the processor controls to output an analysis result based on the analysis,
wherein the processor outputs factor information related to cell efficiency based on the analysis result.

17. The server of claim 13, wherein the processor comprises:
a data collector configured to collect data from the plurality of process apparatuses for manufacturing the solar module; and
a data processor configured to perform data processing based on the data from a plurality of process apparatuses collected by the data collector to select a feature, and perform analysis for the plurality of process apparatuses based on the selected feature.

18. The server of claim 17, wherein the processor further comprises an information provider for outputting analysis result information based on the analysis.

19. The server of claim 18, wherein the data processor comprises:
a character extractor configured to select a feature by performing data processing, based on the data from the plurality of process apparatuses; and
a data analyzer configured to perform analysis on the plurality of process apparatuses based on the selected feature.

20. The server of claim 13, wherein the processor receives structured data comprising sensor data and measurement data from the plurality of process apparatuses, and receives unstructured data comprising machine log data, sensor log data, and alarm log data from the plurality of process apparatuses.
